(19) United States
(12) Patent Application Publication
(10) Pub. No.: US 2023/0259663 A1
(43) Pub. Date: Aug. 17, 2023

(54) Geometric-composition method for multi-contact resolution between multiple rigid objects

(71) Applicant: The Board of Trustees of the Leland Stanford Junior University, Stanford, CA (US)

(72) Inventors: Shameek Ganguly, Milpitas, CA (US); Oussama Khatib, Stanford, CA (US)

(21) Appl. No.: 18/025,888

(22) PCT Filed: Oct. 5, 2021
(86) PCT No.: PCT/US2021/053568

§ 371 Date: Mar. 11, 2023

Related U.S. Application Data
(60) Provisional application No. 63/088,741, filed on Oct. 7, 2020.

(51) Int. Cl. G06F 30/10

(52) U.S. Cl. CPC G06F 30/10; B25J 9/1656

(57) ABSTRACT

Fast and stable methods are provided for estimating contact forces at multiple contact patches for multi-contact interactions between a robot and objects in its environment. Additionally, the estimated contact forces are physically consistent, and provide a useful to substitute to measured forces using sensors. Embodiments of this invention can be programmed as computer- implemented method(s) into a simulation software to produce smooth motion of the robot and objects in its environment without artifacts such as inter-penetration between bodies and unexpected oscillations.

### FIELD OF THE INVENTION

This invention relates to robotic manipulators and methods for multi-contact interactions or collisions with objects.

### BACKGROUND OF THE INVENTION

Modern tools for developing control programs for robotic manipulators include digital models of the workspace and dynamic simulations, either non-interactive or interactive, with a haptic/VR/human-machine interface. A common requirement of simulators used in such applications is to model collision and contact interactions between the robot and objects in the workspace.

In modeling such interactions, the simulator’s task is to compute a smooth motion of the bodies in contact without inter-penetration. Furthermore, contact forces must be computed at each contact interface between the robot and its workspace, which can be presented to the control program or a haptics interface through virtual sensors. Applications for simulation of robotic manipulators in contact-driven tasks require stable and smooth estimates of contact forces.

Current methods of modeling multi-contact interactions between multiple rigid objects use polygon meshes. Two polygonal meshes in contact can generate a large list of contact points, leading to jitter and computational inefficiency in determining the contact forces. Since objects in motion produce a different set of contact points at each time step, a jitter in the contact forces also results in jittery simulated motion of the objects and the robot.

The present invention addresses these limitations of polygon-mesh modeling and provides technology to generate smooth contact forces in computer simulations, robotics and haptic/VR environments.

### SUMMARY OF THE INVENTION

### Definitions

Body links are defined as the constitutive rigid sections of a robotic manipulator, or of its end-of-arm-tooling, which may be connected to one or more other body links through a joint that allows relative motion between the body links such as translation or rotation.
Objects are defined as body links, rigid bodies either of another device, robot or part of or in the environment. An object in one or more objects is defined as an object or a body link of another robot or in an environment the robot is interacting with.
Shape Primitives are defined as closed shapes with a finite volume, which may be represented in an analytical, implicit or parametric form. Examples are a cylinder, a sphere, a box, a line swept sphere, a cone, a box swept sphere, a disc swept sphere, a polyhedron, or a generalized cylinder.
A Rigid Body Frame is defined as a Cartesian measurement frame, assumed to be embedded in a particular rigid body, such that the origin of the frame translates with the body, and the coordinate axes rotate with the body.
A Common Contact Frame is defined as a rigid body frame embedded instantaneously in both bodies in contact at a contact surface, where the constraints in relative motion of the two bodies due to the contact are expressed.
A Center of Pressure of a contact surface is defined as a point on the surface where the net moment exerted by the contact force at each point on the surface sums to zero.
A contact surface (or contact patch) is defined as a set of all points where one shape primitive is in contact with another shape primitive where the two shape primitives belong to two different bodies.
A composition operation is defined as a mathematical rule to construct a single composite shape of finite volume that fits a part of a rigid body from two individual shapes, each of which can either be a shape primitive or a composite shape itself.
Contact Constraints are defined as mathematical inequalities that describe the allowable velocities or accelerations of a pair of bodies that are in contact, as well as the allowable contact force and moment between them.
A line swept sphere is defined as a parametric shape generated by expanding each point on a specified line segment to a sphere of a specified radius.
A box swept sphere is defined as a parametric shape generated by expanding each point on and inside a specified box to a sphere of a specified radius.
A disc swept sphere is defined as a parametric shape generated by expanding each point on a specified circular disc to a sphere of a specified radius.
A generalized cylinder is defined as a parametric shape generated by moving a circular disc along a curved open-ended non-intersecting line segment, where the radius of the disc may vary continuously with the distance along the segment from one end (but may never be zero).
A multi-contact interaction between a robot and its environment is defined as a state of the system where two or more contact patches are present simultaneously.

In one example, the present invention is a method for determining contact dynamics at an interface of a robot having one or more body links interacting with one or more objects. This method distinguishes the steps of fitting geometric shape primitives combined through composition operations (e.g. a union, an intersection, or a difference) for each of the one or more body links and each of the one or more objects the one or more body links are interacting with. A distance is then determined between each of the fitted geometric shape primitives. Contact surfaces are then determined for each pair of the fitted geometric shape primitives where the distance is zero or below a threshold. A common contact frame is determined whose original lies at a center of pressure, where the center of pressure is computed at each of the determined contact surfaces. Provided those determinations, the contact force vector and a contact moment vector are then determined at each of the common contact frames.

In one example, the step of computing the common contact frame further includes the step of determining geometric characteristics of each contact surface. Geometric characteristics are a surface normal, a curvature, or principle axes of curvature.

In yet another example, the step of determining a contact force vector and a contact moment vector further includes the step of computing projected dynamics of the one or body links in terms of a relative linear and angular motion between the pairs at each common contact frame.

In still another example, the method includes using constraints in determining a contact force and a torque for each common contact frame. The constraints incorporate friction equations and non-penetration equations.

Compared to conventional simulators that use polygonal meshes, embodiments of this invention provide a fast and stable method for estimating the contact forces at multiple contact patches for multi-contact interactions between a robot and objects in its environment. Additionally, the estimated contact forces are physically consistent, and provide a useful to substitute to measured forces using sensors. Embodiments of this invention programmed as computer-implemented method(s) into a simulation software can produce smooth motion of the robot and objects in its environment without artifacts such as inter-penetration between bodies and unexpected oscillations.

Embodiments of the invention can be used for commercial simulation or analysis software catering to several applications. The method can be used for multi-body simulation where it can predict the motion and contact forces arising in machines. The method can be used in computer games to compute the dynamics of objects and characters that the players are interacting with. The method can be used for several applications in the field of robotics - to evaluate the design of a robot in virtual deployments, to develop offline motion plans, to develop reactive controllers or to design motion trajectories in real-time. The method can be used in interactive VR environments to generate virtual force feedback on a haptic device.

In each of the above applications, the embodiments of this invention improve the computational speed and stability. Benchmarks against a conventional method of computing contact forces showed that the method provides significant improvement in computational speed. The difference in time taken to compute contact forces between the conventional method and the present method sharply increases as the complexity of the object shapes is increased. Additionally, an embodiment of the method in a simulation software was shown to produce smooth motion of objects in contact, closer to physically correct motion, as compared to a conventional simulator using polygonal meshes. Unphysical oscillations in the motion of the objects was reduced by up to 80%.

### BRIEF DESCRIPTION OF THE DRAWINGS

FIG. 1 shows according to an exemplary embodiment of the invention examples of shape primitives considered in the method.

FIG. 2 shows according to an exemplary embodiment of the invention an example of real object shape and approximation as composition of shape primitives such as spheres, cylinders, disc swept spheres and generalized cylinders.

FIG. 3 shows according to an exemplary embodiment of the invention examples of a contact patch between pairs of obj ects. (Top) surface contact patch between teapot and table, (Middle) line contact between teapot lid and teapot, (Bottom) multiple point contacts between fingers and teapot handle.

FIG. 4 shows according to an exemplary embodiment of the invention a contact between a pair of objects resolved by determining the origin and axes of the Common Contact Frame, as well as the contact force F_{C} and moment M_{C} acting equally on both objects and in opposite directions.

FIG. 5 shows according to an exemplary embodiment of the invention a flow chart or processing pipeline depicting contact resolution for a single contact patch by determining the CC-Frame origin and the contact force/moment vector F_{C}. Readers are referred to U.S. Provisional Application 63/088741 filed Oct. 7, 2020 to which this application claims the benefit of priority for the flow chart. The flow chart herein is stated differently for publication purposes where numerals refer to the box text in the flow chart as filed in the priority document.

510 = Start.
512 = Is CCF available from last iteration.
514 = Set CCF to contact patch centroid.
516 = Project last CCF origin to current contact patch.
518 = Recompute dynamics constraint at current CCF
520 = Compute translational and rotational slip state.
522 = Check whether CCF origin is inside surface, on a line / straight edge, or at a point/line end / boundary point.
524 = Assemble and solve equality constraints linear system to get Fc.
526 = Apply dynamics constraint to get ϑ_{C}.
528 = Set Fc = 0.
530 = Is Fz ≥ 0?
532 = Is friction cone satisfied?
534 = Are COP constraints satisfied?
536 = Compute slip acceleration direction.
538 = Set slip state to slipping.
540 = Subroutine: compute updated CCF origin.
542 = Are rotational motion inequality constraints satisfied?
544 = Change contact state to add moment constraint.
546 = Return CCF, Fc, ϑ_{C}.

FIG. 6 shows according to an exemplary embodiment of the invention a flow chart or processing pipeline for subroutine to displace CC-Frame origin when COP constraints are violated.

FIG. 7 shows according to an exemplary embodiment of the invention possible transitions in contact state in the absence of collisions.

FIGS. 8A-B show combined according to an exemplary embodiment of the invention a flow chart or processing pipeline for a full numerical simulation implemented using methods 1 and 2 presented in this invention.

FIG. 9 shows according to an exemplary embodiment of the invention in modeling the contact between a foot of a humanoid robot and a planar surface. (Top) input forces on the robot are joint torques applied by motors and gravitational force on each body link. (Middle) a possible determined pose of the Common Contact Frame by the invented method, in the interior of the contact patch (shown as white rectangle) as long as the foot touches flat across the planar surface. (Bottom) a possible determined pose of the Common Contact Frame by the invented method, at the edge of the foot, on a contact line segment (shown as white line) when the foot transitions to toe-touch.

### DETAILED DESCRIPTION

Simulation of mechanical and electromechanical systems such as robots requires modeling of the system kinematics, dynamics and contact interactions. It also requires propagation of an initial state of the system over time such that the rates of state change are physically consistent. Simulating multi-contact interactions further requires methods to model the geometry of the objects in the simulated environment, to determine the distance between geometric shapes of the objects, to determine the interaction forces between objects in contact and to determine a contact-consistent motion of such objects.

In addressing the problems in the art, this invention introduces the following methods:
Method 1: Use of shape primitives to model the geometry of objects as a composition of primitive shapes with certain properties that yields a description of a contact patch geometry when two objects are in contact.
Method 2: Use of a Common Contact Frame to determine contact forces and the center of pressure between each pair of objects in contact either at a point, along a line or across a closed planar surface, and to resolve a multi-contact interaction in a system of rigid bodies with or without articulation constraints.

In Method 1, the geometric shape of a complex object is represented in simulation as a composition of primitive shapes that are parametrizable or analytical in nature. Union, intersection or difference operations (also referred to as composition operations) can be used to combine shape primitives into complex object shapes. Such a decomposition can be pre-computed either ground-up from CAD models of simulated objects, or using automated fitting techniques. During time simulation, the distance between each pair of objects is queried at each step, either following an optimization of broad phase separation of object pairs or without such a broad phase. The distance between object pairs is computed through a distance computation between the groups of primitives that compose the two object shapes. When two objects are determined to be in contact due to zero distance between their shape surfaces, the contact patch is computed as a set of points, line segments and surface patches bounded by primitive surfaces.

In Method 2, the contact force/moment required at each contact patch between object pairs is determined. The Common Contact Frame (CC-Frame) is a specified body-fixed coordinate frame located in the convex hull of the contact patch that is shared by both bodies in contact at that patch. In particular, the CC-Frame origin is located at the center of pressure of the contact patch in the method. During time simulation, the CC-Frame at each contact patch is not known a priori, although that information might be available from previous time steps of the simulation and can be used as an initial approximation. A computer-implemented algorithm simultaneously computes the location of the CC-Frame as well as the contact forces/moments required to enforce non-interpenetration between the rigid bodies and simulate surface friction. Spatial rotational and translation constraints are enforced using the CC-Frame method in a unified, global fashion across each contact patch. The computed contact forces and moments can be used during numerical integration of the system state to generate physically consistent trajectories of the rigid objects that can be presented with or without graphical display.

### Method 1

Use of shape primitives to model the geometry of objects as a composition of primitive shapes with certain properties that yields a description of a contact patch geometry when two objects are in contact.

In the method, the overall object shape is approximated using a composition operation on the analytical representations of its component parts.

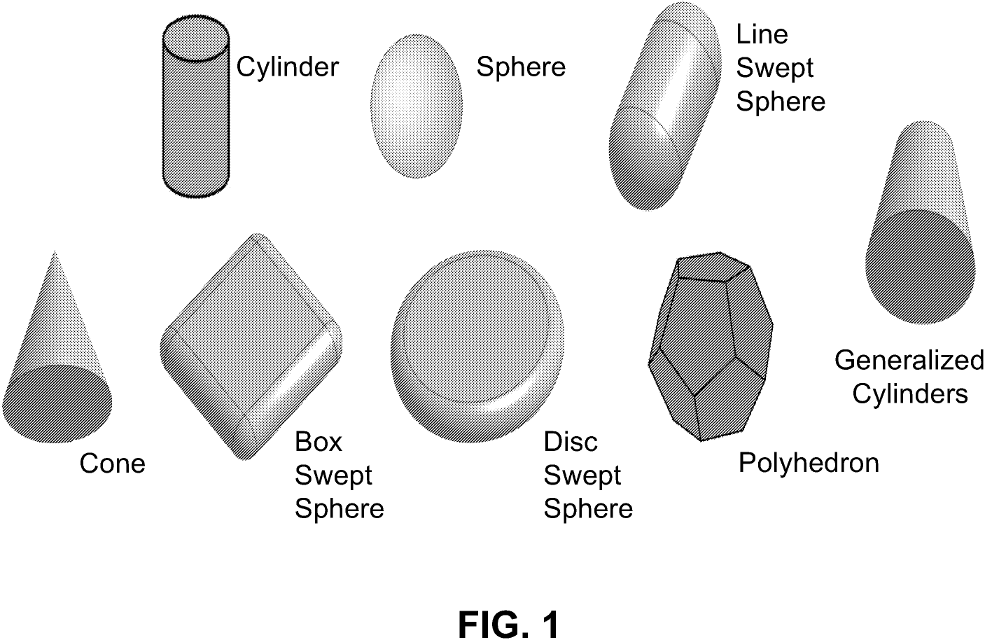

Let S_{i,j}(x, y, z) = 0 represent the j^{th} shape primitive which is part of the i^{th} object shape in the simulated environment. Each shape primitive S_{i,j} represents the surface of a closed, convex set. FIG. 1 shows shape primitives considered in this method.

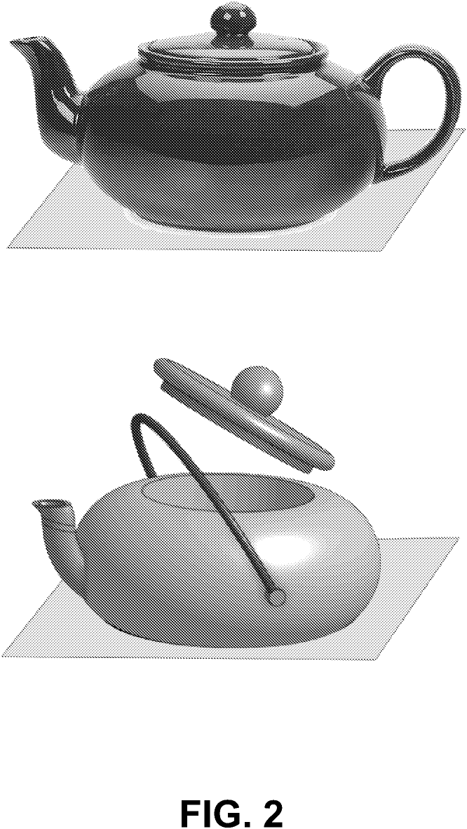

Each object shape Sᵢ is represented as a composition of shape primitives, where one of three composition operations is used in joining two shapes (e.g. in FIG. 2):

$$\begin{matrix}\text{Union:} {S}_{i , {j}_{1}} {}_{{j}_{2}} = \\ \left\{\left(x , y , z\right) \left|{S}_{i , {j}_{1}} \left(x , y , z\right) \left(\leq 0\right\}\right)\right) ∪ \left\{\left(x , y , z\right) \left|{S}_{i , {j}_{2}} \left(x , y , z\right) \left(\leq 0\right\}\right)\right)\end{matrix} \qquad \text{(i)}$$

$$\begin{matrix}\text{Intersection:} {S}_{i , {j}_{1} {j}_{2}} = \\ \left\{\left(x , y , z\right) \left|{S}_{i , {j}_{1}} \left(x , y , z\right)\right) \leq \left(0\right\} ∩ \left\{\left(x , y , z\right) \left|S \left({}_{i , {j}_{2}} \left(x , y , z\right) \leq 0\right\}\right)\right)\right)\end{matrix} \qquad \text{(ii)}$$

$$\begin{matrix}\text{Difference:} {S}_{i , {j}_{1} {j}_{2}} = \\ \left\{\left(x , y , z\right) \left|{S}_{i , {j}_{1}} \left(x , y , z\right)\right) \leq \left(0\right\} ∩ \left\{\left(x , y , z\right) \left|S \left({}_{i , {j}_{2}} \left(x , y , z\right) \leq 0\right\}\right)\right)\right)\end{matrix} \qquad \text{(iii)}$$

Each composition yields a shape part S_{i,j1j2... jk} and the whole shape is a composition of its shape parts. Shape parts cannot be empty sets.

At each time step in the simulation, the objects that are in contact and the shape of the contact patch are determined. To determine which objects are in contact, the minimum distance between a pair of objects is computed. Since this is a computationally expensive process, a shape covering is pre-computed using a bounding volume hierarchy (BVH) of spheres. Each BVH is composed as a tree of spheres where a sphere at a parent node completely envelops each sphere in its subtree, each leaf sphere envelopes the whole or a portion of a shape primitive for the shape being covered, and the parent node sphere of the whole tree completely envelops the object shape.

Let Bᵢ₁ and Bᵢ₂ represent the BVHs of two object shapes. Then, shapes Sᵢ₁ and Sᵢ₂ are intersecting only if the BVHs B_{i,1} and B_{i,2} are intersecting at one or more leaf nodes. Testing for the intersection between BVH B_{i,1} and B_{i,2} is defined as a coarse intersection test. If the coarse intersection test is positive, a list of the potentially intersecting shape parts for each of the two shapes is returned. If the coarse intersection test between two shapes is positive, the pairwise distance between the shape parts are computed to determine if the distance between the two object shapes is below a predefined threshold for contact, ∈_{C}.

### Method 2

Use of a Common Contact Frame to determine contact forces and the center of pressure between each pair of objects in contact either at a point, along a line or across a closed planar surface, and to resolve a multi-contact interaction in a system of rigid bodies with or without articulation constraints.

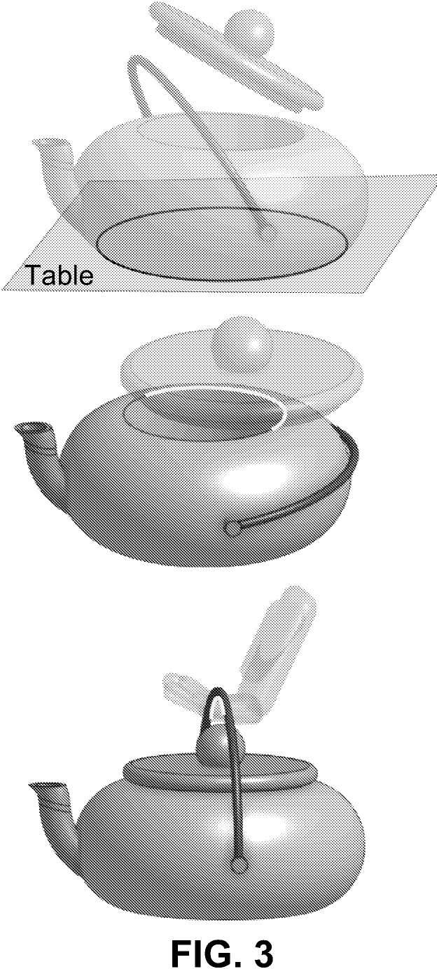

After computing the contact patches, the i^{th} contact patch Gᵢ where i = 1,2,... d_{c} is obtained for d_{c} simultaneous contacts between the bodies. The contact patches (e.g. in FIG. 3) are grouped together into contact islands where each island I has an independent set of articulated bodies in contact with each other. Therefore, the contacts occurring in one island are dynamically isolated from the contacts occurring in another island.

At each contact patch, in order to avoid inter-penetration, a repulsive contact force must be applied on both bodies in contact. State-of-the-art solvers solve for the contact force at each contact point on the contact patch between the bodies. This leads to a large computational problem to determine a feasible set of contact forces that obey the laws of physics, including friction, momentum and non-adhesion. The individual forces are then aggregated and applied to each rigid body to determine the resulting motion of the articulated body. The computer-implemented method of this invention directly computes the aggregated force and moment instead on each rigid body, thus achieving better computational run time.

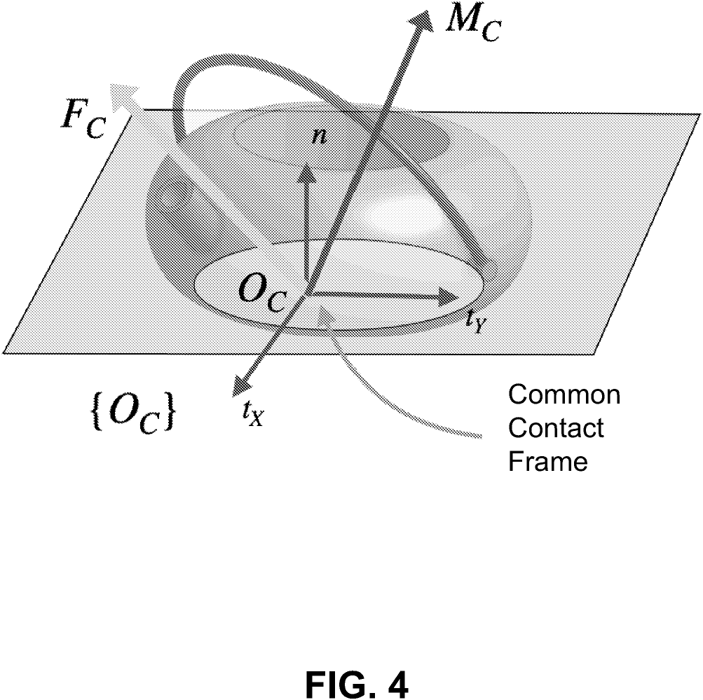

In the method, the contact constraints between two rigid bodies are described at a single Cartesian frame specified at the contact patch shared between the bodies. The frame origin is specified by a spatial position vector with respect to an inertial frame in the simulation world. The frame directions are specified as follows: ‘z’ axis points in the direction of the normal non-penetrative force, ‘x’ and ‘y’ axes point in two orthogonal directions perpendicular to the ‘z’ axis. Typically, the ‘z’ axis aligns with the common normal to the two body surfaces at the frame origin and the ‘x’ and ‘y’ axes align with the tangent plane. This frame is called as the Common Contact Frame (CC-frame) as it is shared between the two bodies, and used to describe the instantaneous relative motion and internal contact forces between the two bodies (see FIG. 4).

The CC-frame origin is designed to coincide with the center of pressure between the two surfaces at the contact patch. This choice makes the CC-frame as well as the contact forces/moment unique, given a particular contact patch geometry, body inertial properties and applied forces on the two bodies. The center of pressure (COP) is defined as the point p_{cop} on the contact patch where the following relation holds for the applied contact forces/moments while satisfying the other contact constraints:

$${M}_{x} = {M}_{y} = 0 \qquad \text{(1)}$$

where Mₓ and M_{y} are the x- and y-components of the contact moment respectively. The above equation will hence forth be referred to as the COP constraints.

For the computed contact forces at the CC-frame to be valid, the following constraints must also hold:

$${F}_{z} = 0 , {a}_{z} \geq 0 \text{or} {F}_{z} \geq 0 , {a}_{z} = 0 \qquad \text{(2)}$$

where F_{z} is the z-component of the contact force and a_{z} is the z-component of the relative translational acceleration of the two bodies. This equation is referred to as the non-penetration constraint.

$$\begin{matrix}\text{If} {v}_{x}^{2} + {v}_{y}^{2} > {δ}_{s t} , {F}_{x} = - {μ}_{t} {F}_{z} \frac{{v}_{x}}{{s}_{t}} , {F}_{y} = - {μ}_{t} {F}_{z} \frac{{v}_{y}}{{s}_{t}} \\ {\text{else either a}}_{x}^{2} + {a}_{y}^{2} = 0 , {F}_{x}^{2} + {F}_{y}^{2} \leq {μ}_{t}^{2} {F}_{z}^{2}\end{matrix} \qquad \text{(3a)}$$

$$\text{or} {a}_{x}^{2} + {a}_{y}^{2} > 0 , {F}_{x} = - {μ}_{t} {F}_{z} \frac{{a}_{x}}{{\dot{s}}_{t}} , {F}_{y} = - {μ}_{t} {F}_{z} \frac{{a}_{y}}{{\dot{s}}_{t}} \qquad \text{(3b)}$$

where µₜ is the translational coefficient of Coulomb friction. νₓ and ν_{y} indicate the relative translational velocity between the bodies at the CC-frame origin and

$${s}_{t} = \sqrt{{v}_{x}^{2} + {v}_{y}^{2}}$$

is the translational slip speed. δₛₜ represents a very small positive number below which the bodies are assumed have no relative translational motion. The above two equations constitute the translational friction constraints.

$$\text{If} {ω}_{z} > {δ}_{s r} , {M}_{z} = - {μ}_{r} {F}_{z} \frac{{ω}_{z}}{{s}_{r}} \qquad \text{(4a)}$$

$$\text{else either} {α}_{z} = 0 , \left|{M}_{z}\right| \leq {μ}_{r} {F}_{z} \text{or} {α}_{z} > 0 , {M}_{z} = - {μ}_{r} {F}_{z} \frac{{α}_{z}}{{\dot{s}}_{r}} \qquad \text{(4b)}$$

where µᵣ is the rotational coefficient of friction that is related to µₜ in the CC-frame method through a length relationship that is dependent on the contact patch geometry. ω_{z} and α_{z} are the relative angular velocity and acceleration respectively between the two bodies measured at the CC-frame origin. sᵣ = |ω_{z}| is the rotational slip speed. δₛᵣ represents a very small positive number below which the bodies are assumed have no relative rotational motion. The above two equations constitute the rotational friction constraints.

Lastly, the kinematic constraints associated with the relative tilting rotation of the two bodies is considered. If the contact patch spans a surface of non-zero area and the CC-frame origin lies in the interior of the patch, the following constraint on the relative angular acceleration applies:

$${α}_{x} = {α}_{y} = 0 \qquad \text{(5a)}$$

When the contact patch is a line segment, and the CC-frame origin lies in the interior of the segment, the following constraint applies:

$${α}^{T} \left(z \times e\right) = 0 \qquad \text{(5b)}$$

where e is the unit norm direction vector along the edge.

If the contact patch is a line segment, and the CC-frame origin lies on one of the two boundary points, the following constraint applies instead:

$$t {α}^{T} e \geq 0 \qquad \text{(5c)}$$

where the indicator variable t = 1 if e points away from the segment at the CC-frame origin, else t = -1.

If the contact patch is a single point, there are no constraints on α.

In case the contact patch constitutes a surface of non-zero area, and the CC-frame origin lies on a straight boundary edge, the following constraints applies:

$${α}^{t} \left(z \times b\right) = 0 , {α}^{T} b \geq 0 \qquad \text{(5d)}$$

where b is the unit direction tangent vector at the CC-frame origin such that z × b points to the interior of the contact patch.

In case the contact patch constitutes a surface of non-zero area and the CC-frame origin lies on a curved edge, the following constraint applies:

$${α}^{t} b \geq 0 \qquad \text{(5e)}$$

Finally, in case the contact patch constitutes a surface of non-zero area and the CC-frame origin lies at a vertex of a surface contact patch shared by two edges with tangent direction vectors b₁ and b₂ respectively at the shared vertex,

$${α}^{T} {b}_{1} \geq 0 , {α}^{T} {b}_{2} \geq 0 \qquad \text{(5f)}$$

Equations 5a-f together constitute the rotational motion constraints.

Put together, equations 1 to 5f are referred to as the contact constraints at the CC-frame.

Although the above constraints are in the mixed form including contact forces/moments and relative translational/angular acceleration at the CC-frame, they can be re-expressed in terms of contact forces/moments alone. To do so, the Contact Space Resolution Method [1] is used which allows determination of the relationship between the contact forces/moments at the CC-frame and the resulting relative accelerations.

$${Λ}_{C} {ϑ}_{C} + {μ}_{C} + {p}_{C} + {F}_{C} = {\overline{J}}_{C} Γ \qquad \text{(6)}$$

where ϑ = [v₁, ω₁, ..., ν_{dc′} ω_{dc}] is the stacked vector of relative translational and rotational velocity at all the contact patches and F_{C} = [F₁, M₁, ..., F_{dc′} M_{dc}] is the stacked vector of contact forces and moments at the contact patches. Matrix Λ_{C} is the contact-space inertia matrix, and vectors µ_{C} and p_{c} represent the Coriolis/centrifugal/gyroscopic and gravity forces respectively projected in the contact space. J_{C} is the Jacobian relating the generalized coordinates velocity to the relative translational/angular velocities between the bodies in contact and Γ is the generalized coordinate forces applied by external non-contact sources such as joint torque controllers. The above relationship is called the contact space dynamics constraint and allows the relative accelerations in the contact constraints to be re-expressed in terms of the contact forces/moments.

To resolve the contact, the location of the CC-frame origin as well as the force/moment along its x-, y- and z- axes are determined at each contact patch for a total of 8 unknown parameters per contact patch.

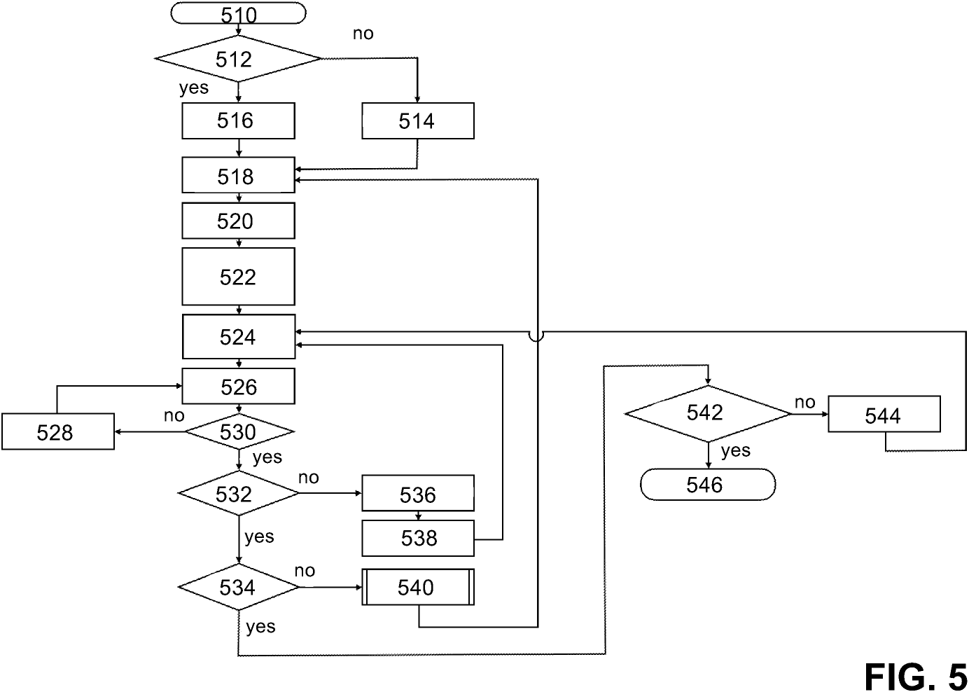

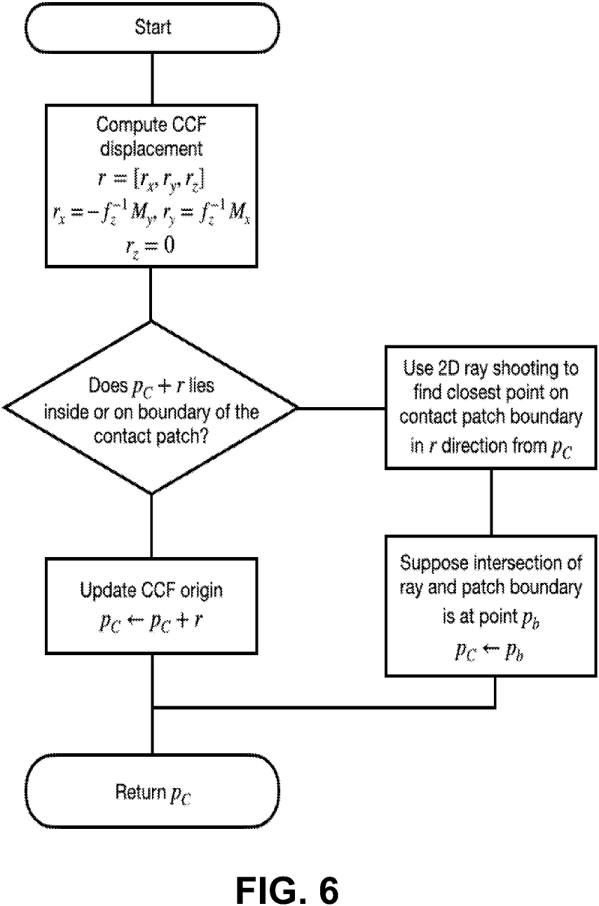

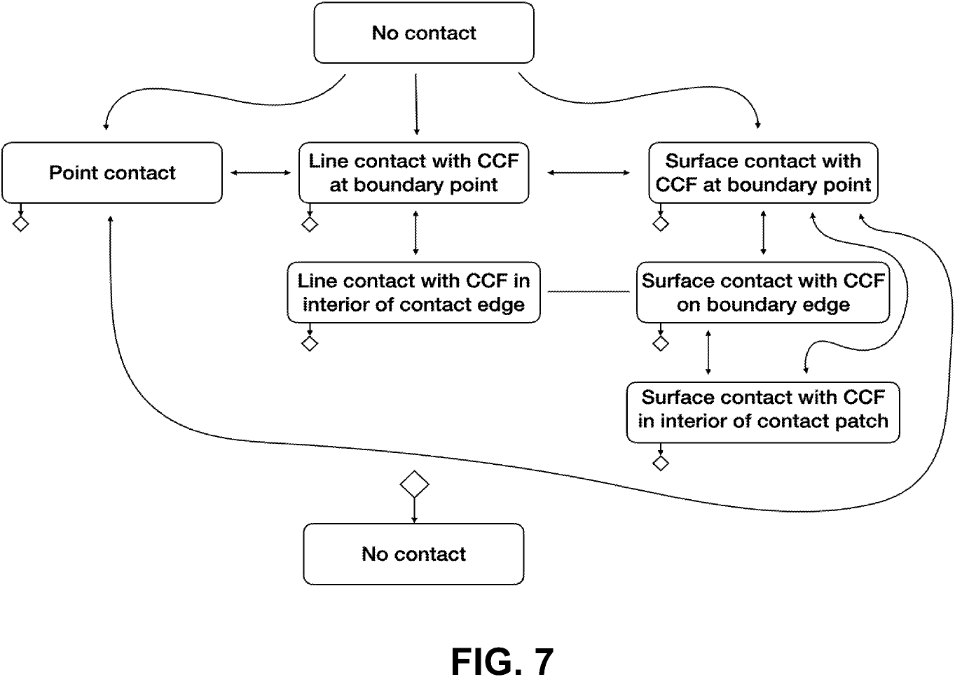

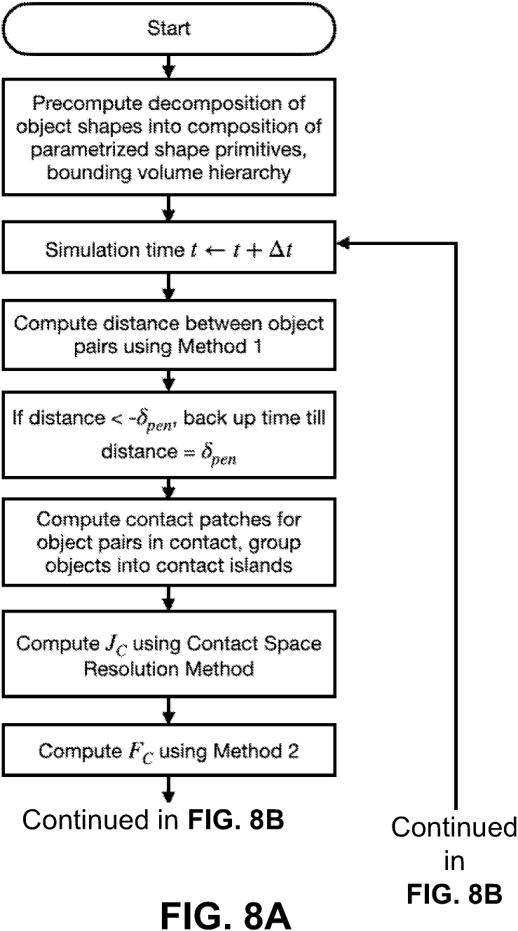

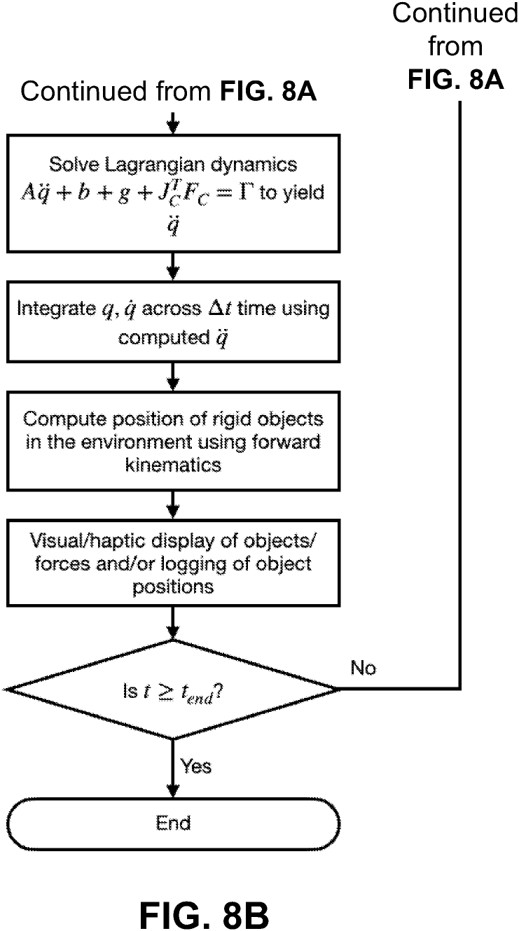

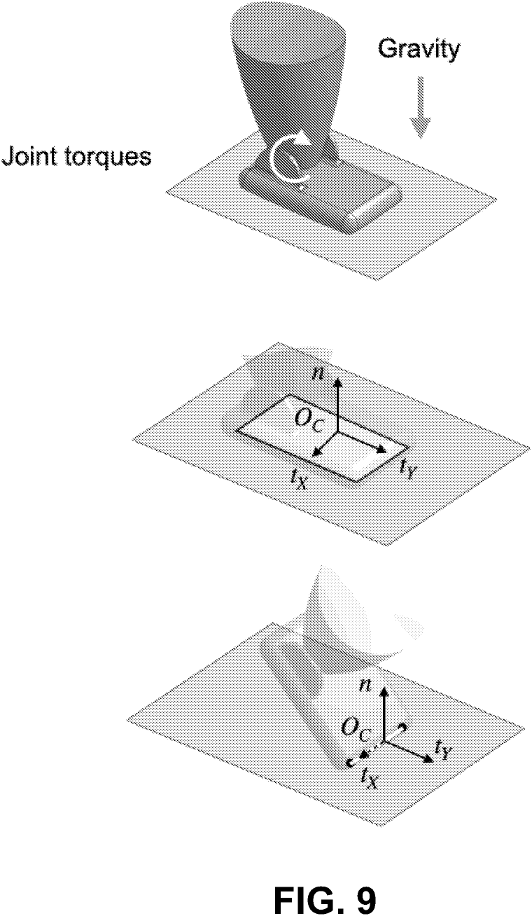

FIG. 5 shows the process presented to solve for the CC-frame (written as CCF in flow chart for brevity) and contact force/moment at a single contact patch when only two objects are present in a contact island. FIG. 6 shows the detailed flow diagram of the subroutine to compute the displacement of the CC-Frame origin when the COP constraint is violated.

When more than two objects are present in a contact island, the process algorithm of FIG. 5 is run independently for each contact patch except at the two steps:
(i) when the linear system of equations is solved for F_{C} and
(ii) when the dynamic constraints are imposed to determine ϑ_{C}.

If some of the contact constraints are redundant between two contact patches, the method checks for independent contact constraints in each of the axis directions associated with the CC-Frame before imposing the constraint at step (i) above. This process can be computationally sped up with a redundancy direction hint that is provided to the process algorithm.

FIG. 7 shows the possible transitions of the constraint configurations at the CC-Frame that are tracked in the method as long as a collision does not occur, for computational efficiency. When a collision occurs, the constraint configuration is recomputed from the contact patch geometry. When the two methods 1 and 2 are combined, a full numerical simulation of an environment having multiple articulated and non-articulated rigid objects can be performed. FIGS. 8A-B show together the flow chart for how this can be accomplished.

Noted is that embodiments of the method of this invention exclude cases where each contact surface is a single point.

What is claimed is:

1. A method of determining contact dynamics at an interface of a robot having one or more body links interacting with one or more objects, comprising:
(a) fitting geometric shape primitives combined through composition operations for each of the one or more body links and each of the one or more objects the one or more body links are interacting with;
(b) determining a distance between each of the fitted geometric shape primitives;
(c) determining contact surfaces for each pair of the fitted geometric shape primitives where the distance is zero or below a threshold;
(d) determining a common contact frame whose original lies at a center of pressure, wherein the center of pressure is computed at each of the determined contact surfaces; and
(e) determining a contact force vector and a contact moment vector at each of the common contact frames.

2. The method as set forth in claim 1, wherein the step of computing the common contact frame further comprises determining geometric characteristics of each contact surface.

3. The method as set forth in claim 2, wherein the geometric characteristics are a surface normal, a curvature, or a principle axes of curvature.

4. The method as set forth in claim 1, wherein the step of determining a contact force vector and a contact moment vector further comprises computing projected dynamics of the one or body links in terms of a relative linear and angular motion between the pairs at each common contact frame.

5. The method as set forth in claim 1, wherein the geometric shape primitive is a closed shape with a finite volume.

6. The method as set forth in claim 1, wherein the geometric shape primitive is a cylinder, a sphere, a box, a line swept sphere, a cone, a box swept sphere, a disc swept sphere, a polyhedron, or a generalized cylinder.

7. The method as set forth in claim 1, wherein the composition operation is a union, an intersection, or a difference.

8. The method as set forth in claim 1, further comprising using constraints in determining a contact force and a torque for each common contact frame.

9. The method as set forth in claim 8, wherein the constraints incorporate friction equations and non-penetration equations.

10. The method as set forth in claim 1, wherein an object in the one or more objects is defined as an object or a body link of another robot or in an environment the robot is interacting with.
